(19) United States
(12) Patent Application Publication
(10) Pub. No.: US 2017/0263860 A1
(43) Pub. Date: Sep. 14, 2017

(54) METHOD OF MANUFACTURING MAGNETORESISTIVE MEMORY DEVICE

(71) Applicant: KABUSHIKI KAISHA TOSHIBA, Tokyo (JP)

(72) Inventors: Satoshi SETO, Kamakura Kanagawa (JP); Minoru AMANO, Sagamihara Kanagawa (JP)

(73) Assignee: KABUSHIKI KAISHA TOSHIBA, Tokyo (JP)

(21) Appl. No.: 15/231,877

(22) Filed: Aug. 9, 2016

Related U.S. Application Data
(60) Provisional application No. 62/306,976, filed on Mar. 11, 2016.

(51) Int. Cl. H01L 43/12; H01L 43/10; H01L 27/22; H01L 43/02; H01L 43/08

(52) U.S. Cl. CPC H01L 43/12; H01L 43/02; H01L 43/08; H01L 27/228; H01L 43/10

(57) ABSTRACT

According to one embodiment, a method of manufacturing a magnetoresistive memory device includes forming a mask on a stacked layer structure disposed on a substrate and constituting a plurality of magnetoresistive elements, etching the stacked layer structure selectively into a plurality of pillars corresponding to the mask by applying an ion beam at a first angle relative to a perpendicular direction to a surface of the substrate, removing deposited films attached to sidewalls of the pillars by applying an ion beam at a second angle greater than the first angle, and etching bottom portions of the pillars by applying an ion beam at a third angle less than the second angle.

### CROSS-REFERENCE TO RELATED APPLICATIONS

This application claims the benefit of U.S. Provisional Application No. 62/306,976, filed Mar. 11, 2016, the entire contents of which are incorporated herein by reference.

### FIELD

Embodiments described herein relate generally to a method of manufacturing a magnetoresistive memory device.

### BACKGROUND

Recently, magnetic random access memories (MRAMs) using magnetic tunnel junction (MTJ) elements as memory elements have been gaining attention. An MTJ element used in an MRAM comprises three thin films, namely, a storage layer and a reference layer of magnetic materials and a barrier layer (insulating layer) interposed therebetween, and is configured to store data based on the magnetization state of the storage layer. In a spin-transfer-torque MRAM using spin injection magnetization reversal techniques, to write data to an MTJ element, current is applied in a perpendicular direction to the film surface of the MTJ element.

### BRIEF DESCRIPTION OF THE DRAWINGS

FIG. 1 is a circuit diagram showing a memory cell array of a magnetoresistive memory device of a first embodiment.

FIG. 2 is a sectional diagram showing the structure of a memory cell portion of the magnetoresistive memory device of the first embodiment.

FIGS. 3A to 3C are sectional diagrams showing the manufacturing procedure of the memory cell portion of FIG. 2.

FIG. 4 is a schematic diagram showing an ion beam irradiation device used for manufacturing the memory cell portion.

FIGS. 5A to 5C are schematic diagrams showing the ion beam irradiation procedure using the device of FIG. 4.

FIGS. 6A to 6C are schematic diagrams showing the shapes of the MTJ element in the respective steps of FIGS. 5A to 5C.

FIGS. 7A and 7B are schematic diagrams showing a method of setting a first angle of incidence.

FIGS. 8A to 8D are explanatory diagrams showing a definition of a space S.

FIGS. 9A to 9C are schematic diagrams showing a simulation result of the memory cell structure of the first embodiment together with comparative examples.

### DETAILED DESCRIPTION

In general, according to one embodiment, a method of manufacturing a magnetoresistive memory device comprises: forming a mask corresponding to an element pattern on a stacked layer structure disposed on a substrate and constituting a plurality of magnetoresistive elements; etching the stacked layer structure selectively into a plurality of pillars corresponding to the mask by applying an ion beam at a first angle of incidence relative to a perpendicular direction to a surface of the substrate; removing deposited films attached to sidewalls of the pillars in the selective etching of the stacked layer structure by applying an ion beam at a second angle of incidence greater than the first angle of incidence; and etching bottom portions of the pillars by applying an ion beam at a third angle of incidence less than the second angle of incidence after the removing of the deposited films.

### First Embodiment

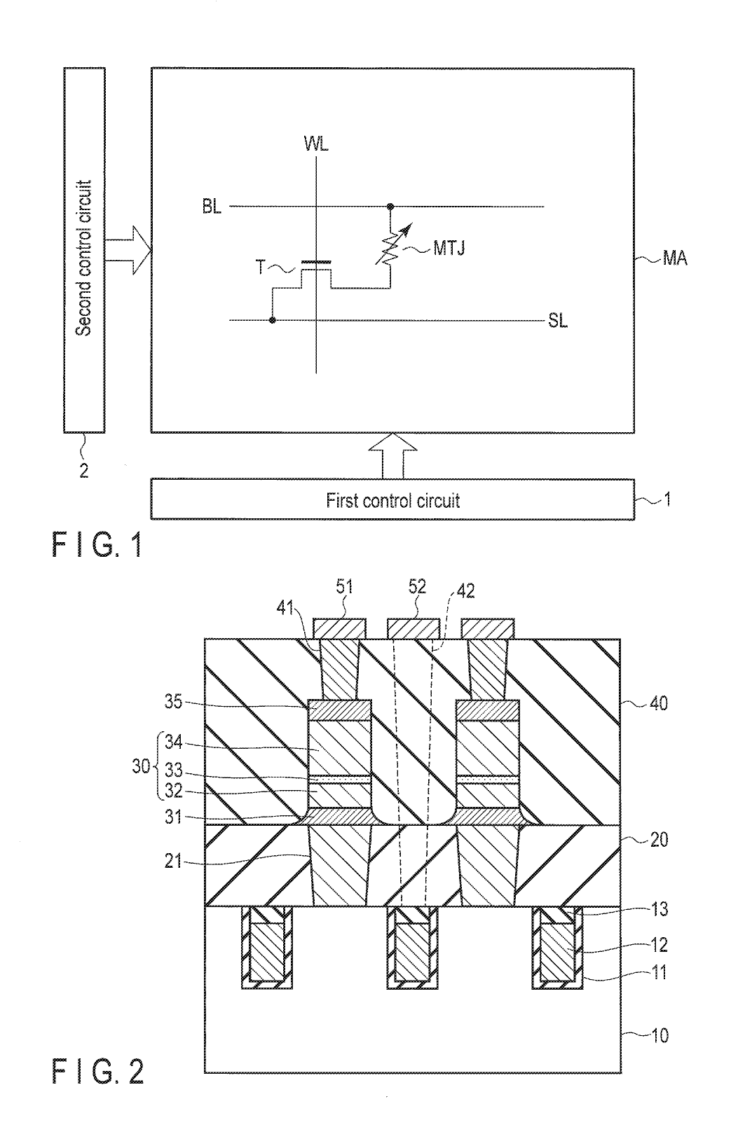

FIG. 1 is a circuit diagram showing a memory cell array of an MRAM of the first embodiment.

A memory cell in a memory cell array MA comprises an MTJ element as a magnetoresistive memory element and a switch element such as a field effect transistor (FET) T connected to each other in series. One end of the series-connected entity (one end of the MTJ element) is connected to a bit line BL, and the other m end of the series-connected entity (one end of the switch element T) is connected to a source line SL.

The control terminal of the switch element, for example, the gate electrode of the FET is connected to a word line WL. The potential of the word line WL is controlled by a first control circuit 1. Further, the potentials of the bit line BE and the source line SE are controlled by a second control circuit 2.

FIG. 2 is a sectional diagram showing the structure of a memory cell portion used for an MRAM of the first embodiment.

A MOS transistor as a switch element is formed on the surface of an Si substrate 10, and an interlayer insulating film 20 of silicon oxide (SiO₂) or the like is formed thereon. The transistor has a buried gate structure in which a gate electrode 12 is buried in a groove in the substrate 10 via a gate insulating film 11. The gate electrode 12 is buried in such a manner as to fill the groove halfway, and a protective insulating film 13 of silicon nitride (SiN) or the like is then formed thereon. Further, although not shown in the drawing, p- and n-type impurities are scattered respectively on the sides of the buried gate structure to form a source/drain region.

Note that the structure of the transistor is not

necessarily the buried gate structure. For example, the transistor may also have a structure in which a gate electrode is formed on the surface of the Si substrate 10 via a gate insulating film. The structure of the transistor may be any structures as long as the transistor can serve as a switch element.

A contact hole is formed in the interlayer insulating film 20 to make a connection to the drain of the transistor, and a bottom electrode (BEC) 21 is buried in the contact hole. The bottom electrode 21 can be W, Ta, tantalum nitride (TaN), titanium nitride (Tits) or the like.

A buffer layer 31 is formed on a part of the bottom electrode 21. The buffer layer 31 can be a material containing Al, Be, Mg, Ca, Sr, Ba, Sc, Y, La, Si, Zr, Hf, W, Cr, Mo, Nb, Ti, Ta, V or the like. Further, the buffer layer 31 may also be a nitride or boride thereof. The nitride or the boride is not necessarily a binary compound consisting of two chemical elements but may be a ternary compound consisting of three chemical elements. That is, the nitride or the boride may also be a compound of a binary compound. Further, the buffer layer 31 may also be formed of a stack of layers of these materials.

A ferromagnetic magnetization free layer, namely, a storage layer (SL [first magnetic layer]) 32 of cobalt-ion-boron (CoFeB) , a tunnel barrier layer (intermediate layer [IL]) 33 of magnesium oxide (MgO), a ferromagnetic magnetization fixed layer, namely, a reference layer (RL [second magnetic layer]) 34 of CoFeB, and a cap layer 35 of Pt, W, Ta, Ru or the like are disposed on the buffer layer 31. That is, an MTJ element 30 comprising the two ferromagnetic layers 32 and 34 and the tunnel barrier layer 33 interposed therebetween and using the tunneling magnetoresistive (TMR) effect is formed.

The storage layer 32 is preferably a material having magnetocrystalline anisotropy such as cobalt palladium (CoPd) or a material having magnetic interface anisotropy such as CoFeB (CFB)/oxide or ion-boron (FeB). The same also applies to the material of the reference layer 34. Further, the reference layer 34 may also be cobalt platinum (CoPt), cobalt nickel (CoNi), CoPd or the like, or a stack of layers thereof.

Note that the composition ratio of the material such as TaN, TiN, MgO, CoFeB, FeB, CoPt, CoNi, CoPd or MgO described in the embodiment does not necessarily stand at 1:1:1 or 1:1. That is, for example, the storage layer SL (first magnetic layer) of CoFeB means the storage layer SL containing Co, Fe and B (but the composition ratio of Co, Fe and B is not limited to any particular ratio). Further, the runnel barrier layer IL (intermediate layer) of IMO means the tunnel barrier layer IL containing Mg and O (but the composition ratio of Mg and O is not limited to any particular ratio). This also applies to the composition ratios of the other materials.

An interlayer insulating film 40 of SiO₂ or the like is formed on the substrate on which the MTJ element 30 is formed. A contact plug (TEC) 41 is buried in the interlayer insulating film 40 and connected to the cap layer 35 on the MTJ element 30. Further, a contact plug 42 is buried in the interlayer insulating film 40 and the interlayer insulating film 20 and connected to the source of the transistor. Still further, an interconnect (BL) 51 and an interconnect (SL) 52 are formed on the interlayer insulating film 40 and are connected respectively to the contact plug 41 and the contact plug 42.

Note that the MTJ element 30 does not necessarily comprise the storage layer 32 on the substrate side and the reference 34 on the other side but may comprise the reference layer 34 on the substrate side and the storage layer 32 on the other side. Further, the MTJ element 30 may further comprise a shift cancelling layer for cancelling or suppressing a stray magnetic field from the reference layer 34.

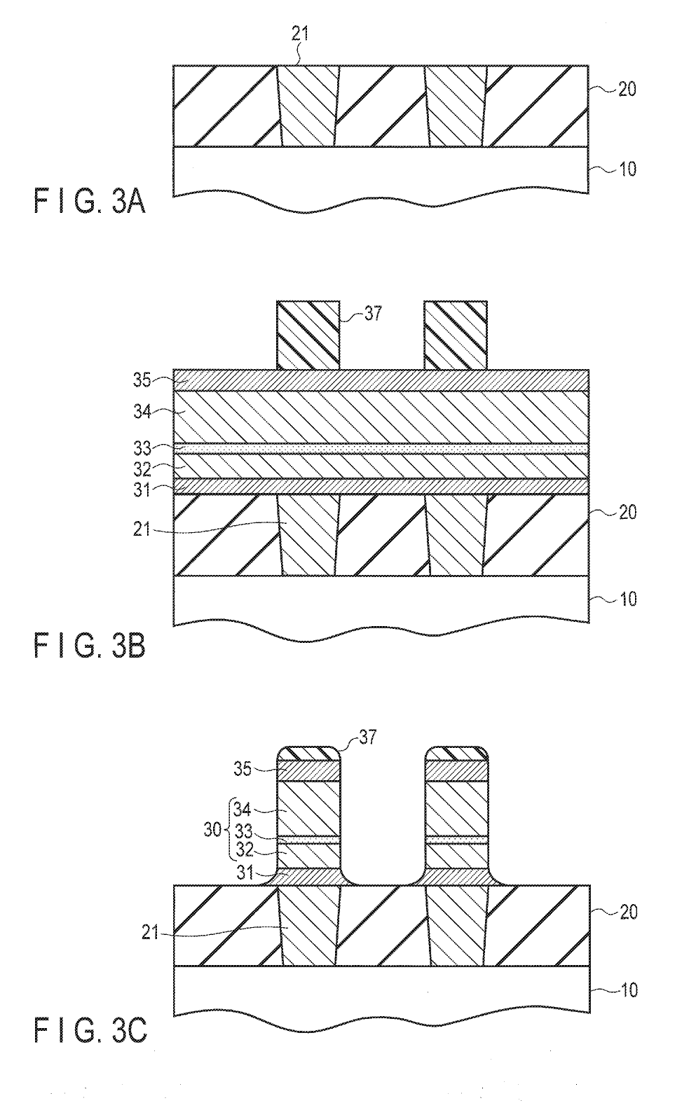

Next, a method of manufacturing the memory cell of FIG. 2 will be described with reference to FIGS. 3A to 3E. Note that the drawings only show from the substrate 10 upwards for the sake of convenience.

First, as shown in FIG. 3A, a MOS transistor (not shown) having a buried gate structure and serving as a switch element is formed in the surface of the Si substrate 10, and then the interlayer insulating film 20 of SiO₂ or the like is deposited on the Si substrate 10 by the chemical vapor deposition (CVD) method. Subsequently, a contact hole is formed in the interlayer insulating film 20 to make a connection to the drain of the transistor, and the bottom electrode 21 of W is then buried in the contact hole. More specifically, a W film is deposited on the interlayer insulating film 20 by the CVD method or the like in such a manner as to fill the contact hole, and the W film deposited on the interlayer insulating film is then removed by a chemical mechanical polishing (CMP) method in such a manner as to leave the W film only in the contact hole. In the burying process, a seed layer of Ti or TiN may also be deposited as an initial layer.

Note that, in FIG. 3A, the bottom electrode 21 has a width substantially the same as that of the eventual MTJ element but may also have a width greater than that. In that case, the MTJ element, which will be described later, will be formed only on the bottom electrode 21.

Then, as shown in FIG. 3B, the magnetic layer 32 of CoFeB or the like is formed on the bottom electrode 21 and the interlayer insulating film 20 via the buffer layer 31 by a sputtering method. The tunnel barrier layer 33 of MgO is then formed on the magnetic layer 32. The magnetic layer 34 of CoFeB or the like is formed on the tunnel barrier layer 33, and the cap layer 35 is then formed thereon. Then, a hard mask (HM) 37 of SiN or the like is formed on the cap layer 35. The HM may remain after the MTJ element manufacturing process to serve as a top electrode. In that case, the HM may contain highly-conductive metal (such as Ta, W or Ti), a nitride of the conductive metal, or a stack of layers thereof. Here, the thickness of the mask 37 is preferably greater than or equal to the film thickness of the stack of layers 31 to 35.

Next, as shown in FIG. 3C, ion beam etching (IBE) using, for example, Ar is applied from the cap layer 35 to the buffer layer 31 to selectively etch the stack of layers down to the bottom electrode 21 or the interlayer insulating film 20 in the element pattern. In this way, the stack of layers is divided into a plurality of pillars.

After that, the interlayer insulating film 40 of SiO₂ or the like, the contact plugs 41 and 42, and the interconnects 51 and 52 are formed accordingly, and the structure of FIG. 2 is thereby manufactured.

Here, the characteristics of the present embodiment, namely, the method of processing the stack of layers 31 to 35 into the MTJ element pattern will be described in detail.

The IBE method is a physical etching method mainly using ion kinetic energy. Therefore, unlike an RIE process, an IBE process is less likely to damage layers by a chemical reaction. Further, in the present embodiment, since an Ar ion beam is applied obliquely, the amount of an etching product deposited on etching sidewalls can be reduced.

Further, in the IBE method, the perpendicularity of the shape of a processing object cannot be maintained unless the physical etching process is performed in consideration of the balance with an etching product reattached to its sidewalls. In the mean time, as the generation ascends and the layout shrinks, to secure the space between adjacent cells, the thickness of the MTJ element and the height of the HM need to shrink accordingly. This is because, otherwise, the MTJ element will be under the shade of the adjacent cells and the beam will not reach the MTJ element, and consequently the perpendicularity of the shape cannot be maintained. Still further, after the etching process, the metal cap layer including the HM should be left for an upper contact.

In consideration of the above points, the IBE process of the present embodiment is performed in three etching steps at three different angles of incidence.

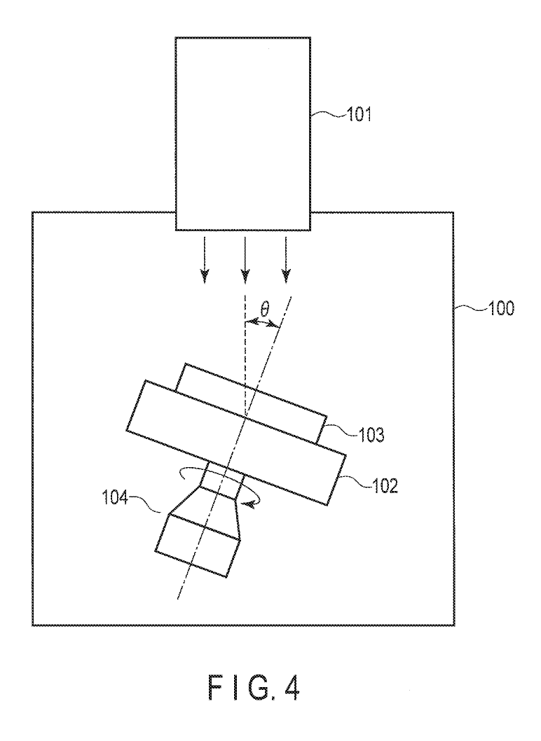

An ion beam irradiation device of the present embodiment has a structure shown in FIG. 4. That is, the ion beam irradiation device comprises an ion source 101 which emits an on beam into a chamber 100 and a stage 102 which is provided in the chamber 100 and on which a sample 103 is mounted. Further, the stage 102 is rotatable by a rotational mechanism 104, and the axis of rotation is tiltable relative to the vertical direction.

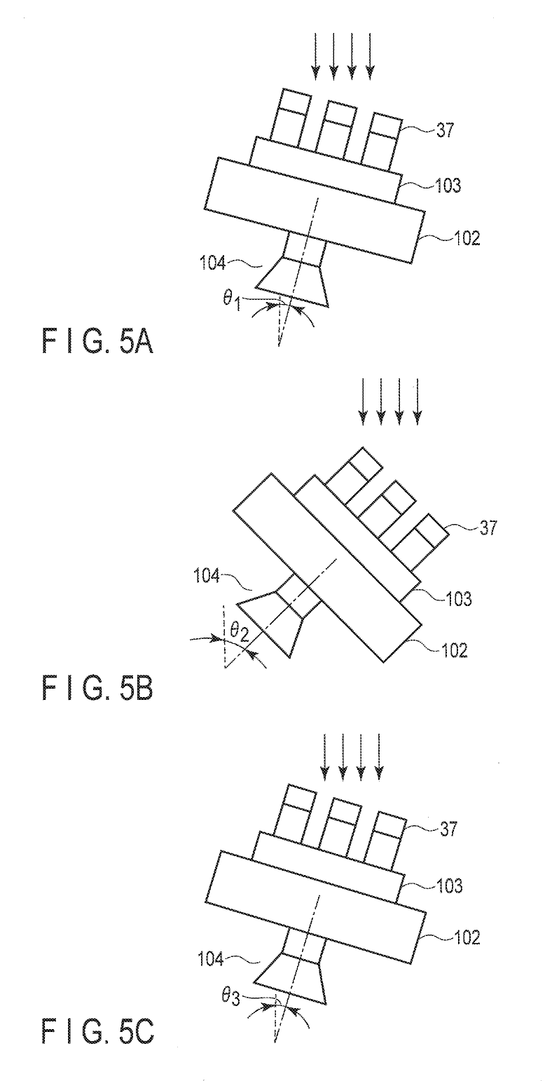

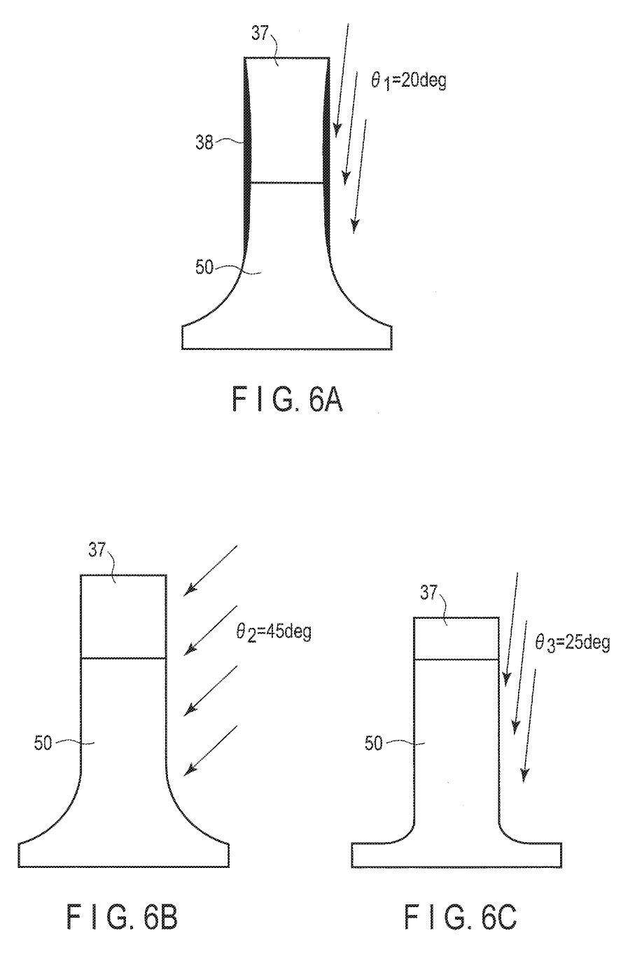

First, in the above-described ion beam irradiation device, as shown in FIG. 5A, the sample 103 is mounted on the stage 102 rotating in a state of being tilted at θ₁=20° relative to the vertical direction and is irradiated with the ion beam emitted from the ion source 101. In this way, as shown in FIG. 6A, a stack of layers 50 constituting the MTJ element is selectively etched in the element pattern. That is, the stack of layers 50 is divided into a plurality of pillars.

In the IBE process of the stack of layers 50, as described above, the field part of the film is etched with the beam at a small angle of incidence (at an small angle relative to the direction perpendicular to the substrate surface) and thus the impact of the shade of adjacent cells is limited. Further, in the IBE process, an etching product (deposited film) 38 is attached to the sidewalls of the pillars, but since the beam is applied obliquely, it is possible to reduce the deposited film 38 as compared to the case of performing the IBE process perpendicularly.

Next, as shown in FIG. 5B, on the stage 102 rotating in a state of being tilted at θ₂=45° relative to the vertical direction, the sample 103 is irradiated with the ion beam emitted from the ion source 101. In this way, as shown in FIG. 6B, the deposited films 38 attached to the sidewalls of the pillars are etched. Here, the beam is applied laterally to reshape the pillars. Further, the side surfaces of the pillars are etched together with the deposited films 38 attached in the first etching step, and the, shapes of the pillars are roughly determined.

Then, as shown in FIG. 5C, on the stage 102 rotating in a state of being tilted at θ₃=25° relative to the vertical direction, the sample 103 is irradiated with the ion beam emitted from the ion source 101. In this way, as shown in FIG. 6C, the bottom portions of the pillars are etched, and the shapes of the pillars are fixed. That is, the beam is applied sharply again to etch the bottom portions of the pillars, and then the etching process ends.

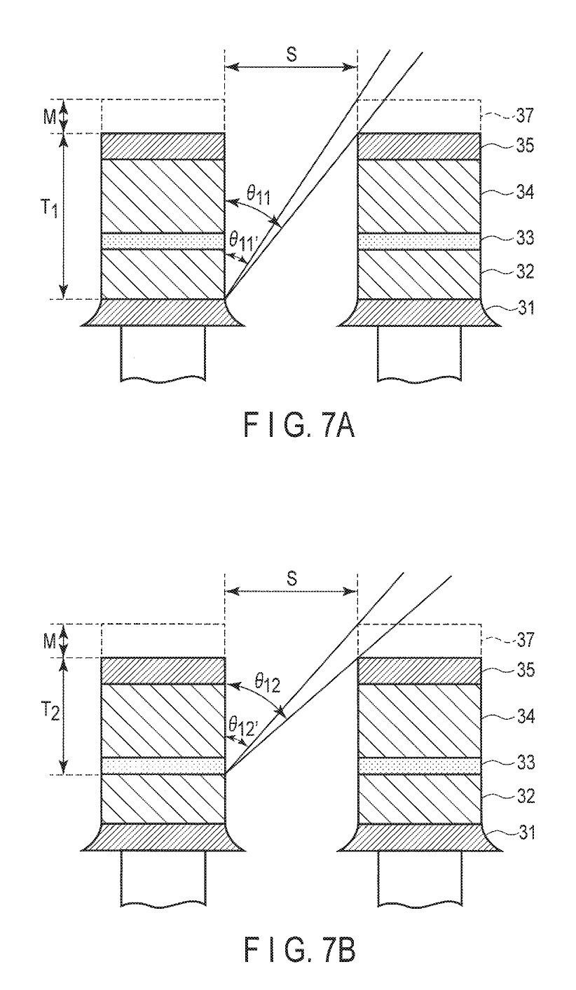

In the first beam irradiation, to divide the stack of layers into a plurality of pillars corresponding to the mask 37, the beam should reach the bottom portion of the stack of layers without being blocked by the mask 37 corresponding to adjacent pillars. More specifically, the ion beam should reach the bottom portion of the storage layer 32. Therefore, as shown in FIG. 7A, the first angle of incidence θ₁₁ may be any angle less than or equal to an angle satisfying the following equation:

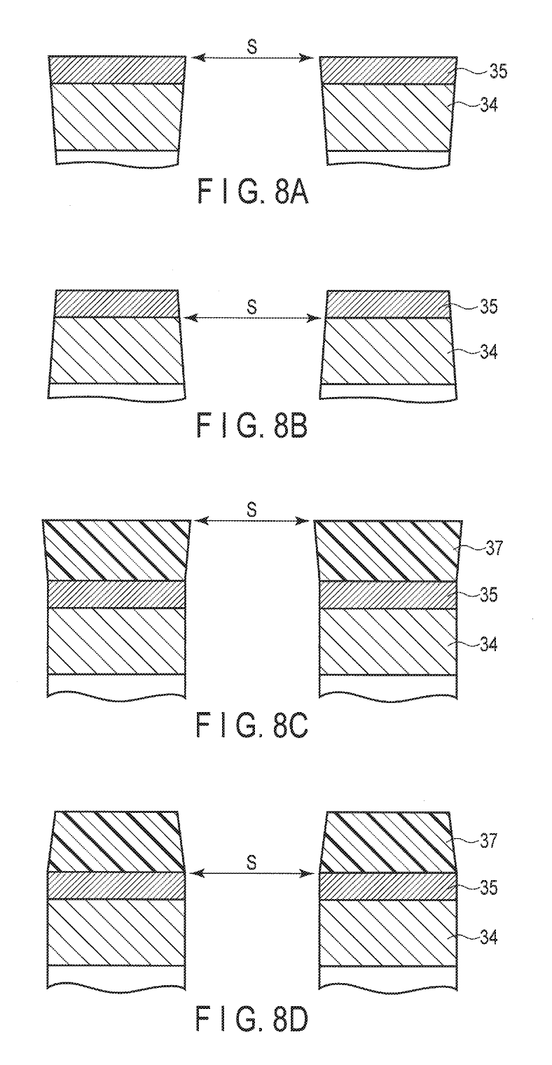

tan(θ₁₁)=S/T₁, (1)

where S is the space between adjacent cells and T1 is the film thickness of the stack of layers (32-35). The space S between adjacent cells corresponds to the shortest distance between adjacent cap layers 35, each of which is the uppermost layer of the stack of layers. That is, as shown in FIG. 8A, for example, when the cap layer 35 is inversely tapered, the space S corresponds to the distance between the uppermost portions of the adjacent cap layers 35. Further, as shown in FIG. 8B, for example, when the cap layer 35 is tapered, the space S corresponds to the distance between the lowermost portions of the adjacent cap layers 35.

Here, in the case of leaving the mask 37, the first angle of incidence θ₁₁′ may be any angle less than or equal to an angle satisfying the following equation:

tan(θ₁₁′)=S/(T₁+M), (2)

where M is the remaining film of the mask 37. The space S between adjacent cells corresponds to the shortest distance between adjacent masks 37, each of which is the uppermost layer of the stack of layers. That is, as shown in FIG. 8C, for example, when the mask 37 is inversely tapered, the space S corresponds to the distance between the uppermost portions of the adjacent masks 37. Further, as shown in FIG. 8D, for example, when the mask 37 is tapered, the space S corresponds to the distance between the lowermost portions of the adjacent masks 37.

Further, the stack of layers is not necessarily divided completely into MTJ elements in the first step. As long as a part of the stack of layers down to the barrier layer 33 is divided, it is possible to divide the stack of layers completely into elements functioning as memory cells in the third step (bottom portion trimming; pillar shaping). Therefore, as shown in FIG. 7B, the first angle of incidence θ₁₂ may be any angle less than or equal to an angle satisfying the following equation:

tan(θ₁₂)=S/T₂, (3)

where S is the space between adjacent cells and T2 is the film thickness of the stack of layers (33-35). As in the case (1), the space S corresponds to the shortest distance between adjacent cap layers 35. That is, the space S corresponds to the distance between the uppermost portions of the adjacent cap layers 35 when the cap layer 35 is inversely tapered, and the space S corresponds to the distance between the lowermost portions of the adjacent cap layers 35 when the cap layer 35 is tapered.

Here, in the case of leaving the mask 37, the first angle of incidence θ₁₂′ may be any angle less than or equal to an angle satisfying the following equation:

tan(θ₁₂′)=S/(T₂+M). (4)

As in the case of (2), the space S corresponds to the shortest distance between adjacent masks 37. That is, the space S corresponds to the distance between the uppermost portions of the adjacent masks 37 when the mask 37 is inversely tapered, and the spacer S corresponds to the distance between the lowermost portions of the adjacent masks 37 when the mask 37 is tapered.

Note that, in the above description, the buffer layer 31 to the cap layer 35 may also be defined as the stack of layers since the stack of layers completely divided in the etching process includes the buffer layer 31.

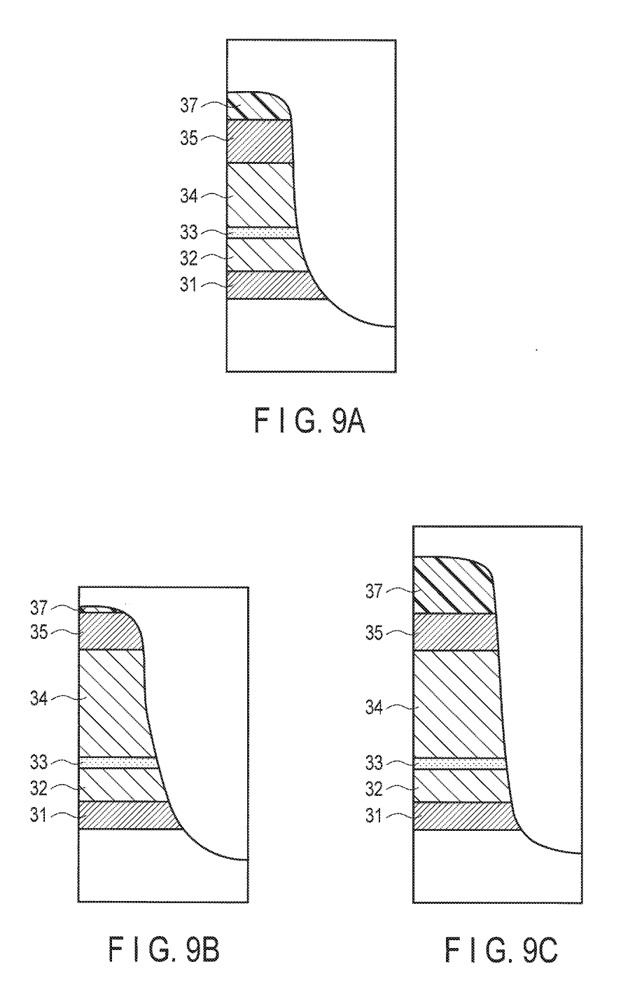

A simulation result of the present embodiment is shown in FIGS. 9A to 9C together with comparative examples. All have processed in an about 60 nm pitch layout.

The comparative example of FIG. 9A is the case of a two-step etching process (step 1: first beam irradiation at an angle of incidence of 45°; step 2: second beam irradiation at an angle of incidence of 25°) and is the case of an MTJ element satisfying the conditions of the taper angle of the side surface of the pillar and of the HM remaining film, that is, an MTJ element having a film thickness of 22 nm. When the HM had a thickness of 50 nm and the MTJ element had a thickness of 22 nm, the remaining HM had a thickness of 14.5 nm and the taper angle was 80.9°.

The comparative example of FIG. 9B is the case of a two-step etching process (step 1: first beam irradiation at an angle of incidence of 45°; step 2: second beam irradiation at an angle of incidence of 25°), and is the case of an MTJ element having a film thickness of 30 nm. When the HM had a thickness of 50 nm and the MTJ element had a thickness of 30 nm, the remaining HM had a thickness of 4.0 nm and the taper angle was 79.7°. In this case, the thickness of the remaining HM is insufficient.

The example of FIG. 9C is, as in the case of the present embodiment, the case of a three-step etching process (step 1: first beam irradiation at an angle of incidence of 20°; step 2: second beam irradiation at an angle of incidence of 45°; step 3: third beam irradiation at an angle of incidence of 25°), and is the case of an MTJ element satisfying the conditions of the taper angle and the HM remaining film, that is, an MTJ element having a film thickness of 30 nm. When the

MM had a thickness of 80 nm and the MTJ element had a thickness of 30 nm, the remaining HM had a thickness of 16.2 nm and the taper angle was 82.7°. As is evident from the above, even in the case of the HM having such a thickness as to be too large to have an impact on adjacent cells under the conditions of the pillar manufacturing process of the comparative examples, that is, even in the case of an MTJ element having a film thickness of 30 nm, it is still possible to achieve a necessary taper angle and a necessary HM remaining film.

Therefore, according to the present embodiment, it is possible to increase the thickness of the MTJ part or increase the thickness of the hard mask while maintaining a tolerable inclination angle of the MTJ element of about 80° (inclination angle is an angle relative to the interlayer insulating film 20).

Consequently, according to the present embodiment, even in the case of a high-density pattern, it is still possible to ensure the perpendicularity of the pillars by the three-step ion beam irradiation, that is, by etching at the first angle of incidence θ₁ to suppress the shadow effect of the HM corresponding to adjacent pillars, etching at the second angle of incidence θ₂ to remove the deposited films, and etching at the third incident angel θ₃ to remove the bottom portions of the pillars. As a result, it is possible to increase the capacity and reliability of the magnetoresistive memory device.

### Modification

Note that the above description is in no way restrictive.

The structure of the MTJ element is not necessarily limited La the structure of FIG. 2 but may be appropriately modified according to the actual manners of implementing the embodiment. Further, the memory cell is not necessarily limited to an MTJ element but may be applied to various other magnetoresistive elements.

The first angle of incidence θ₁ is riot necessarily limited to an angle satisfying the equation θ₁≦tan⁻¹(S/T) or θ₁≦tan⁻¹[S/(T+M)] but may he any angle as long as the ion beam reaches the bottom portions of the pillars formed in the selective etching process without being blocked by the mask corresponding to adjacent pillars.

The second angle of incidence θ₂ is not necessarily 45°, but may be any angle as long as the deposited films on the sidewalls of the pillars can be etched efficiently, and is preferably an angle of greater than or equal to 45°. The third angle of incidence θ₃ is not necessarily 25°, but may be any angle as long as the bottom portions of the pillars can be etched and the shapes of the pillars can be fixed efficiently, and is preferably be an angle greater than the first angle of incidence θ₁ but smaller than 45°.

The structure of the ion beam irradiation device is not necessarily limited to the structure of FIG. 4 but may be appropriately modified according to the actual manners of implementing the embodiment. For example, instead of tilting the axis of rotation of the stage relative to the vertical direction, it is also possible to title the irradiation angle of the ion beam relative to the vertical direction. Further, the ion beam to be emitted from the ion source is not necessarily an Ar beam but may be an ion beam of various inert elements such as Ne, He, Kr, Xe and N.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a magnetoresistive memory device, comprising:
forming a mask corresponding to an element pattern on a stacked layer structure disposed on a substrate and constituting a plurality of magnetoresistive elements;
etching the stacked layer structure selectively into a plurality of pillars corresponding to the mask by applying an ion beam at a first incident angle relative to a perpendicular direction to a surface of the substrate;
removing deposited films attached to sidewalls of the pillars in the selective etching of the stacked layer structure by applying an ion beam at a second incident angle greater than the first incident angle; and
etching bottom portions of the pillars by applying an ion beam at a third incident angle less than the second incident angle, after the removing of the deposited films.

2. The method of claim 1, wherein the substrate is mounted on a stage rotatable about an axis perpendicular to the surface of the substrate, and the stage is rotated in the selective etching of the stacked layer structure, the removing of the deposited films, and the etching of the bottom portions of the pillars.

3. The method of claim 1, wherein an inequality T/S>1 is satisfied where T is a film thickness of the stacked layer structure and S is a space in the element pattern.

4. The method of claim 1, wherein the first incident angle is an angle determined such that the ion beam reaches the bottom portions of the pillars formed in the selective etching without being blocked by the mask corresponding to the adjacent element pattern.

5. The method of claim 1, wherein the first incident angle is less than or equal to an angle θ satisfying an equation tan(θ)=S/T where T is a film thickness of a major part of the stacked layer structure and S is a space in the element pattern.

6. The method of claim 5, wherein the magnetoresistive element is an MTJ element comprising a plurality of magnetic layers and a nonmagnetic layer between the magnetic layers, and
the film thickness T is a thickness from an upper surface of the magnetic layer disposed at a bottom of the stacked layer structure to a top surface of the stacked layer structure.

7. The method of claim 1, wherein the first incident angle is less than or equal to an angle θ satisfying an equation tan(θ)=S/(T+M) where T is a film thickness of a major part of the stacked layer structure, M is a height of the mask remaining after the selective etching, and S is a space in the element pattern.

8. The method of claim 1, wherein the second incident angle is an angle greater than or equal to 45 degrees.

9. The method of claim 1, wherein the third incident angle is an angle less than 45 degrees.

10. The method of claim 1, wherein a height of the mask is greater than or equal to a film thickness of the stacked layer structure.

11. A method of manufacturing a magnetoresistive memory device, comprising:
forming a mask corresponding to an element pattern on a stacked layer structure disposed on a substrate and constituting a plurality of magnetoresistive elements;
etching the stacked layer structure selectively in the element pattern by applying an ion beam while rotating the substrate at a first incident angle relative to a perpendicular direction to a surface of the substrate and less than or equal to an angle θ satisfying an equation tan(θ)=S/T where T is a film thickness of a major part of the stacked layer structure and S is a space in the element pattern, wherein deposited films are attached to sidewalls of the element pattern in the selective etching of the stacked layer structure;
removing the deposited films by applying an ion beam while rotating the substrate at a second incident angle greater than or equal to 45 degrees to the stacked layer structure; and
etching bottom portions of the element pattern by applying an ion beam while rotating the substrate at a third incident angle less than 45 degrees to the stacked layer structure, after the removing of the deposited films.

12. The method of claim 11, wherein an inequality T/S>1 is satisfied where T is a film thickness of the stacked layer structure and S is a space in the element pattern.

13. The method of claim 12, wherein the magnetoresistive element is an MTJ element comprising a plurality of magnetic layers and a nonmagnetic layer between the magnetic layers, and
the film thickness T is a thickness from an upper surface of the magnetic layer disposed at a bottom of the stacked layer structure to a top surface of the stacked layer structure.

14. The method of claim 11, wherein a thickness of the mask is greater than or equal to a film thickness of the stacked layer structure.

15. A method of manufacturing a magnetoresistive memory device, comprising:
forming a mask corresponding to an element pattern on a stacked layer structure disposed on a substrate and constituting a plurality of magnetoresistive elements;
applying an ion beam at a first incident angle relative to a perpendicular direction to a surface of the substrate to divide the stacked layer structure into a plurality of pillars corresponding to the mask;
applying an ion beam at a second incident angle greater than the first incident angle, after the applying of the ion beam at the first incident angle; and
applying an ion beam at a third incident angle less than the second incident angle, after the applying of the ion beam at the second incident angle.

16. The method of claim 15, wherein the substrate is mounted on a stage rotatable about an axis perpendicular to the surface of the substrate, and the stage is rotated in the applying of the ion beam at the first incident angle, the applying of the ion beam at the second incident angle, and the applying of the ion beam at the third incident angle.

17. The method of claim 15, wherein the first incident angle is an angle determined such that the ion beam reaches the bottom portions of the pillars formed in the applying of the ion beam at the first incident angle without being blocked by the mask corresponding to the adjacent element pattern.

18. The method of claim 15, wherein the first incident angle is less than or equal to an angle θ satisfying an equation tan(θ)=S/T where T is a film thickness of a major part of the stacked layer structure and S is a space in the element pattern.

19. The method of claim 15, wherein the first incident angle is less than or equal to an angle θ satisfying an equation tan(θ)=S/(T+M) where T is a film thickness of a major part of the stacked layer structure, M is a height of the mask remaining after the applying of the ion beam at the first incident angle, and S is a space in the element pattern.

20. The method of claim 15, wherein the second incident angle is an angle greater than or equal to 45 degrees, and the third incident angle is an angle less than 45 degrees.
